(19) United States
(12) Patent Application Publication
(10) Pub. No.: US 2016/0141195 A1
(43) Pub. Date: May 19, 2016

(54) Multi-shaft Vacuum Manipulator Shafting Accuracy Testing Device

(71) Applicant: SHANGHAI JIAO TONG UNIVERSITY, Shanghai (CN)

(72) Inventors: Pinkuan Liu, Shanghai (CN); Jing Wu, Shanghai (CN)

(21) Appl. No.: 15/011,542

(22) Filed: Jan. 30, 2016

(30) Foreign Application Priority Data
Aug. 2, 2013 (CN) 201310336884.3

(51) Int. Cl. H01L 21/68; G01D 5/26

(52) U.S. Cl. CPC H01L 21/681; G01D 5/264

(57) ABSTRACT

This invention provides a multi-shaft vacuum manipulator shafting testing device that is simple in structure, convenient for assembly and disassembly and strong in practicality. That device consists of test bed, manipulator direct drive unit, angle encoder installation support, angle encoder, connecting flange and laser displacement detecting device. The manipulator direct drive unit is mounted on the test bed through the flange. The angle encoder installation support is fixed through bolt on the test bed on one end, and the other end has the angle encoder installed on it through bolt. One end of the connecting flange connects with the shafting of the manipulator direct drive unit. The other end is connected by a flexible coupling with the angle encoder shaft. The flexible coupling compensates the axial movement error and the nonalignment error between the encoder and connecting flange to avoid too much force acting on the bearing of the angle encoder. The laser displacement detecting device consists of two laser displacement sensors and a two-dimensional mobile platform, which can adjust the range of measurement. This invention has such advantages as high measurement accuracy, convenient test operation and wide application scope and low test cost.

### TECHNICAL FIELD

This invention relates to a kind of shafting accuracy testing device, more specifically to a kind of multi-shaft vacuum manipulator shafting accuracy testing device.

### INVENTION BACKGROUND

With the development of the semi-conductor industry, bundling equipment and vacuum robot appear to be more and more important in pursuit of increasing production efficiency. At present, bundling equipment and vacuum robot technologies are in a starting stage domestically. The shafting accuracy of a vacuum robot is an important performance index thereof. Whether in robot development stage or production stage, a set of simple, efficient, stable and reliable shafting accuracy testing device is needed in order to realize performance testing and quality control to vacuum robot.

Currently, the shafting accuracy testing device being used the most broadly is a measurement device adopting electric eddy current displacement sensor. This kind of measurement device is low in measurement accuracy and the operation in the measurement process is trivial and its use is inconvenient. The existing electric eddy current displacement sensor shafting measurement device has a range not adjustable. Repeated installation and commissioning is usually required in measurement, the operation is trivial and its use is very inconvenient. And times of repeated installation are easy to cause interference that influences the measurement accuracy. At the same time, as the range is not adjustable, that kind of measurement device can only measure one shafting with the application scope being narrow and a different measurement device having to be set up for a different shafting resulting in a high measurement cost. Besides, the existing electric eddy current displacement sensor measurement device can only be used to measure metal materials and can not satisfy the measurement requirement for a non-metal material shafting.

### SUMMARY OF INVENTION

In view of the defects in the existing technology, the purpose of this invention is to provide a simple, efficient, stable and reliable multi-shaft vacuum manipulator shafting accuracy testing device.

According to one aspect of this invention, a kind of multi-shaft vacuum manipulator shafting accuracy testing device is provided, with test bed 1, manipulator direct drive unit 2, connecting flange 3, flexible coupling 4, angle encoder 5, angle encoder installation support 6 and laser displacement detecting device 7, angle encoder installation support 6 and test bed 1 being connected, angle encoder 5 and angle encoder installation support 6 being connected; the connecting flange being set up on the test bed 1 with both upper and lower ends connecting respectively with the flexible coupling 4 and manipulator direct drive unit 2, flexible coupling 4 and angle encoder 5 being connected, laser displacement detecting device 7 and connecting flange 3 being connected.

Preferably, the manipulator direct drive unit 2 includes manipulator mounting flange 21 and manipulator drive shaft 22, with the manipulator mounting flange 21 connecting with the test bed 1, the manipulator drive shaft 22 connecting respectively with the manipulator mounting flange 21 and the connecting flange 3.

Preferably, the laser displacement detecting device 7 includes two laser displacement sensors 71 and two-dimensional mobile platform 72, with the two-dimensional mobile platform 72 connecting with the connecting flange 3, the two laser displacement sensors 71 being set up on the two-dimensional mobile platform 72.

Here is the working process of this invention: When the manipulator drive shaft 22 rotates, it drives the connecting flange 3, the flexible coupling 4, the angle encoder 5′s shaft to rotate, so that the angle encoder 5 can measure the dynamic movement condition of the manipulator drive shaft 22. By adjusting the position of the two-dimensional mobile platform 72 in the plane, the laser displacement detecting device 7 can align the laser displacement sensor 71 with the center of the manipulator drive shaft 22 and be in an effective measurement range to realize measurement to the surface distance of the outer circle of the connecting flange 3. And through comprehensive analysis to the data of the two laser displacement sensors 71, such dynamic running conditions as radial run-out and inclination angle, etc. for the manipulator drive shaft 22 can be obtained.

In comparison with the existing technology, this invention has the following beneficial effects: this invention adopts laser displacement sensor and has an adjustable device—two-dimensional mobile platform. Through the two-dimensional mobile platform, the range can be adjusted for different measurement objects conveniently, and multi-shafting measurement can be realized merely by changing different models of connecting flanges. Adapting to multi-shafting measurement, it avoids trivial repeated installation and commissioning, expands the application scope and reduces the testing cost effectively. At the same time, by adopting the laser displacement measurement method, this invention can also satisfy the measurement requirement for a non-metal material shafting. As it adapts to measurement of shafting in different materials, the application scope is wide. Besides, this invention can realize different shafting measurements merely by changing different models of connecting flanges with the installation integrity between multiple shafts being maintained, the interference of installation measurement to shafting accuracy being minimized and the measurement accuracy being high. Therefore, in comparison with the existing technology, this invention has such advantages as high measurement accuracy, convenient testing operation, wide application scope and low testing cost.

### EXPLANATION TO FIGURES

By reading and referring to the detailed description of following figures to the non-restrictive embodiment example, other features, purposes and advantages of this invention will become more apparent:

FIG. 1 is the three-dimensional structural diagram for the multi-shaft vacuum manipulator shafting accuracy testing device of this invention;

FIG. 2 is the structural section view for the multi-shaft vacuum manipulator shafting accuracy testing device of this invention;

FIG. 3 is the angle encoder installation schematic diagram for the embodiment example of this invention;

FIG. 4 is the manipulator drive shaft connection schematic diagram for the embodiment example of this invention.

In the above figures, 1 is test bed, 2 is manipulator direct drive unit, 21 is manipulator mounting flange, 22 is manipulator drive shaft, 3 is connecting flange, 4 is flexible coupling, 5 is encoder, 6 is angle encoder installation support, 7 is laser displacement detecting device, 71 is laser displacement sensor and 72 is two-dimensional mobile platform.

### SPECIFIC EMBODIMENT

In the following, a specific embodiment example will be combined to make a detailed description to this invention. The following embodiment example will help the technical people in this field further understand this invention. However, it does not limit this invention in any manner. It should be pointed out that the common technical people in this field can make some variations and improvements under the prerequisite of not divorcing from the conception of this invention. All these belong to the protective range for this invention.

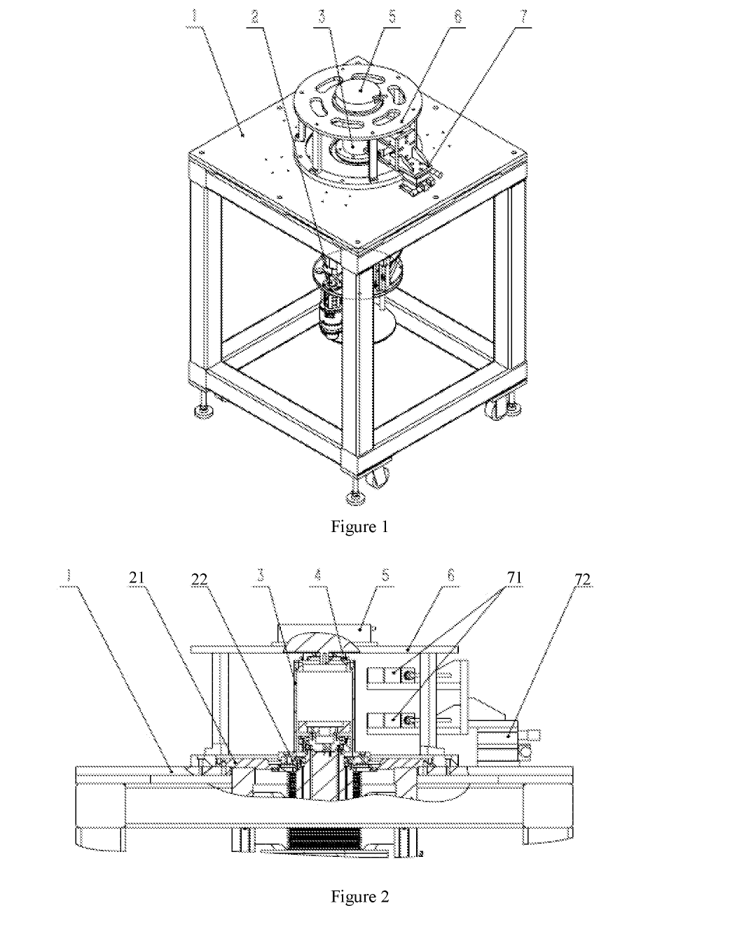

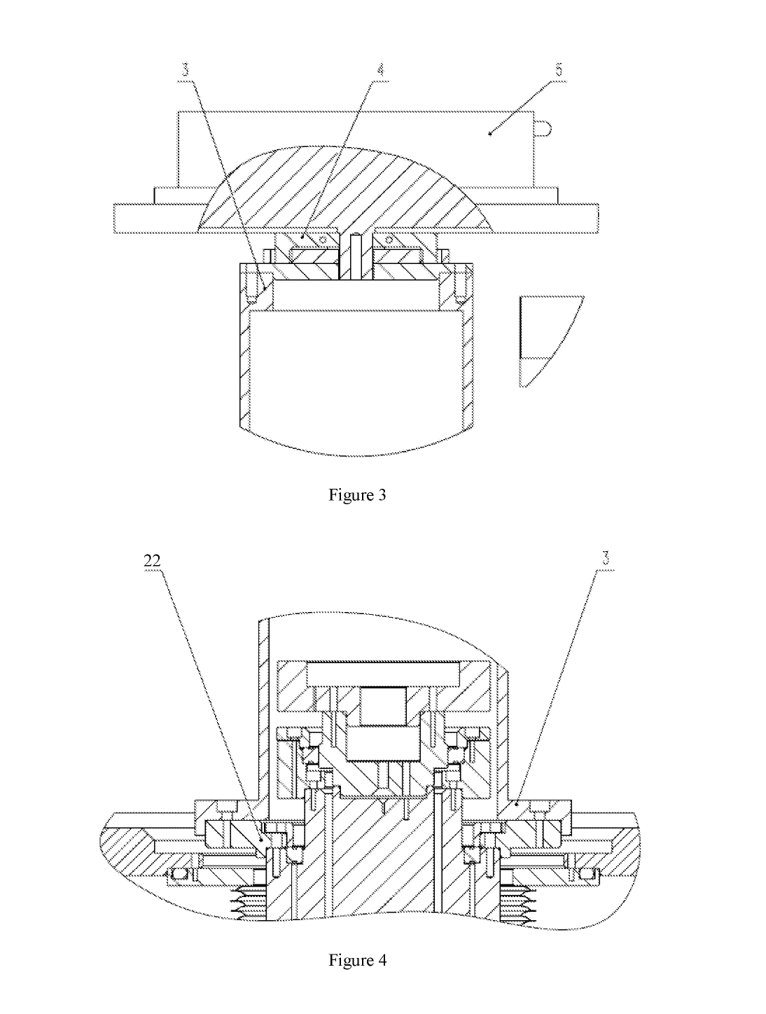

Please refer to FIG. 1 to FIG. 4, a kind of multi-shaft vacuum manipulator shafting accuracy testing device, test bed 1, manipulator direct drive unit 2, connecting flange 3, flexible coupling 4, angle encoder 5, angle encoder installation support 6 and laser displacement detecting device 7. The manipulator direct drive unit 2 include the manipulator mounting flange 21 and the manipulator drive shaft 22. The laser displacement detecting device 7 includes two laser displacement sensors 71 and two-dimensional mobile platform 72.

The angle encoder installation support 6 connects with the test bed 1, the angle encoder 5 connects with the angle encoder installation support 6; the connecting flange is set up on the test bed 1 with both upper and lower ends connecting respectively with the angle encoder 5 and manipulator direct drive unit 2. The flexible coupling 4 is set up between the connecting flange 3 and the angle encoder 5. The laser displacement detecting device 7 connects with the connecting flange 3.

The manipulator direct drive unit 2 is connected through the mounting flange 2-1 on the working plane of the test bed 1. One end of the connecting flange 3 mates through bolt with the outer circle of the connecting end of the manipulator drive shaft 2-2, and is connected through bolt. The other end mates with the flexible coupling 4 and is connected through bolt. The inner circle and bottom surface of the base plate of the angle encoder installation support 6 mate respectively with the outer circle of the manipulator mounting flange 2-1 and the working plane of the test bed 1 to realize positioning, and then are fixed on the test bed 1 through bolts. The shaft of the angle encoder 5 connects with the flexible coupling 4, and is positioned through its shoulder on the inner wall of the angle encoder connection support 6, which is connected and fixed by bolt, and both of them are positioned through the line shaft hole in between to ensure the coaxiality of the angle encoder 5 and the manipulator shafting. On the other side of the working plane of the test bed 1, the laser displacement detecting device 7 is installed to realize two-dimensional mobile adjustment. The two-dimensional mobile platform 72 of the laser displacement detecting device 7 connects with the connecting flange 3, with the two laser displacement sensors 71 being set up on the two-dimensional mobile platform 72.

In this invention, the angle encoder installation support 6 and the manipulator mounting flange 2-1 realize the coaxial positioning requirement through shaft-hole mating. One end of the connecting flange 3 connects with the manipulator drive shaft 2-2, and the other end is connected by the flexible coupling 4 with the angle encoder 5's shaft, so that the angle encoder 5 can measure the dynamic changes of the manipulator drive shaft 2-2. The flexible coupling 4 the axial movement error and the nonalignment error between angle encoder 5′s shaft and connecting flange 3 to avoid too much force acting on the bearing of the angle encoder 5. The two laser displacement sensors 71 can adjust the measurement range through the two-dimensional mobile platform 72 and obtain indirectly the dynamic running data of the manipulator drive shaft 2-2 through measurement to the outer cylindrical surface of the connecting flange 3.

Here is the specific working process of this invention: when the manipulator drive shaft 22 rotates, it drives the connecting flange 3, the flexible coupling 4, the angle encoder 5's shaft to rotate, so that the angle encoder 5 can measure the dynamic running condition of the manipulator drive shaft 22. By adjusting the position of the two-dimensional mobile platform 72 in the plane, the laser displacement detecting device 7 can align the laser displacement sensor 71 with the center of the manipulator drive shaft 22 and be in an effective measurement range to realize measurement to the surface distance of the outer circle of the connecting flange 3. And through comprehensive analysis to the data of the two laser displacement sensors 71, such dynamic running conditions as radial run-out and inclination angle, etc. for the manipulator drive shaft 22 can be obtained. Besides, measurement to different manipulator drive shafts can be realized merely by replacing with a connecting flange of a corresponding specification and adjusting the distance of the laser displacement sensor.

A description is made to a specific invention embodiment example above. It needs to understand that this invention is not limited to the above specific embodiment. The technical people in this field can make various variations or modifications within the range of the Claim and this will not influence the substantial contents of this invention.

1. A kind of multi-shaft vacuum manipulator shafting accuracy testing device characterized by including test bed (1), manipulator direct drive unit (2), connecting flange (3), flexible coupling (4), angle encoder (5), angle encoder installation support (6) and laser displacement detecting device (7), the said angle encoder installation support (6) connecting with the said test bed (1), the said angle encoder (5) connecting with the said angle encoder installation support (6); the said connecting flange is set up on the said test bed (1) with the two upper and lower ends connecting with the said flexible coupling (4) and manipulator direct drive unit (2) respectively, the said flexible coupling (4) connecting with the said angle encoder (5), the said laser displacement detecting device (7) connecting with the said connecting flange (3).

2. According to claim 1, the said multi-shaft vacuum manipulator shafting accuracy testing device is characterized by the said manipulator direct drive unit (2) including manipulator mounting flange (21) and manipulator drive shaft (22), the said manipulator mounting flange (21) connecting with the said test bed (1), the said manipulator drive shaft (22) connecting with the said manipulator mounting flange (21) and connecting flange (3) respectively.

3. According to claim 1, the said multi-shaft vacuum manipulator shafting accuracy testing device is characterized by the laser displacement detecting device (7) including two laser displacement sensors (71) and two-dimensional mobile platform (72), the said two-dimensional mobile platform (72) connecting with the said connecting flange (3), the said two laser displacement sensors (71) being set up on the said two-dimensional mobile platform (72).
